(19) United States
(12) Patent Application Publication
(10) Pub. No.: US 2024/0113055 A1
(43) Pub. Date: Apr. 4, 2024

(54) STRUCTURE FOR HYBRID BOND CRACKSTOP WITH AIRGAPS

(71) Applicant: INTERNATIONAL BUSINESS MACHINES CORPORATION, ARMONK, NY (US)

(72) Inventors: Nicholas Alexander Polomoff, Hopewell Junction, NY (US); Eric Perfecto, North Salem, NY (US); Katsuyuki Sakuma, Fishkill, NY (US); Mukta Ghate Farooq, Hopewell Junction, NY (US); Spyridon Skordas, Troy, NY (US); Sathyanarayanan Raghavan, Ballston Lake, NY (US); Michael P. Belyansky, Halfmoon, NY (US)

(21) Appl. No.: 17/937,429

(22) Filed: Sep. 30, 2022

(51) Int. Cl. H01L 23/00; H01L 25/065

(52) U.S. Cl. CPC H01L 24/08; H01L 24/03; H01L 24/80; H01L 25/0657; H01L 2224/02125; H01L 2224/02145; H01L 2224/0215; H01L 2224/03019; H01L 2224/0361; H01L 2224/03622; H01L 2224/08145; H01L 2224/80895; H01L 2224/80896; H01L 2225/06524; H01L 2225/06527; H01L 2225/06593; H01L 2924/3512

(57) ABSTRACT

A hybrid bonded semiconductor structure includes a first substrate and a second substrate each having an interface joined in a hybrid bond. Each substrate has a die portion and a crackstop structure adjacent the die portion. One or more voids in the first substrate and the second substrate are formed in or about a portion of a periphery of each crackstop structure. At least some of the one or more voids in the first substrate and the second substrate are substantially aligned to form a unified void with airgaps across the hybrid bond interface.

### BACKGROUND

### Technical Field

The present disclosure generally relates to integrated circuit structures having crackstops, and more particularly, to hybrid bonded structures having crackstops.

### Description of the Related Art

During the fabrication of integrated circuits on a wafer, operations such as dicing of the substrate and dielectric layers introduce external stresses that may cause microcracks during the fabrication process. In addition, microcracks may exist or form from internally-caused stresses. Microcracks can propagate in both the substrate and dielectric layers and cause circuit failures. Although crackstops are used to arrest the propagation of microcracks, hybrid bonded structures present additional challenges in arresting microcrack propagation, such as at the areas where the hybrid bonding occurs.

### SUMMARY

According to one embodiment, a hybrid bonded semiconductor structure includes a first substrate and a second substrate each having an interface joined in a hybrid bond. Each substrate has a die portion and a crackstop structure adjacent the die portion. One or more voids in the first substrate and the second substrate are formed in or about a portion of a periphery of each crackstop structure. At least some of the one or more voids in the first substrate and the second substrate are substantially aligned to form a unified void with airgaps across the hybrid bond interface. The voids stop microcracks from spreading particularly across the bonding interface that can cause a catastrophic failure of the semiconductor device.

In one embodiment, the crackstop structure of the first substrate and the second substrate is joined at the hybrid bond interface. Extending the crackstop structure to the hybrid bond interface reduces the possibility that a microcrack may propagate along the interface below the interface and damage the die.

In one embodiment, at least some of the voids formed in each of the first substrate and the second substrate are differently shaped. Differently-shaped voids can create different volume airgaps that may the propagation of the microcracks.

In one embodiment, the one or more voids include a plurality of voids at least some of which are differently sized. The different size voids can assist with alignment, and some voids are effective for microcracks stoppage caused by internal stresses, whereas other sizes are more effective for microcrack stopping caused by external stresses, such as dicing of the wafers.

In one embodiment, a plurality of voids are arranged in succession extending across the hybrid bond interface. The succession of voids decreases the possibility that a crack may bypass a single void.

In one embodiment, each hybrid bond interface includes a back-end-of-line (BEOL) interconnect level, and the unified void is a least partially filled with a dielectric or a polysilicon material that is different from a material of the hybrid bond interface. Filling the void with a dielectric has a different effect on stopping crack propagation.

In one embodiment, the one or more voids in the first substrate and the second substrate are ring-shaped. The various shapes provide different amounts of stoppage of microcracks.

In one embodiment, the one or more voids in the first substrate and the second substrate are arranged as non-contiguous rings. The non-contiguous rings have multiple voids in succession to control the microcrack propagation.

In one embodiment, the one or more voids in the first substrate and the second substrate are circular-shaped. Circular-shaped voids may provide a larger surface area to arrest the propagation of microcracks.

In one embodiment, the one or more voids are filled with a material that is different from a material forming the crackstop structure and/or the hybrid bond interface. The voids provide an airgap to prevent the microcracks. However, filling in a dielectric material in the void may provide for a more stable operation as airgaps are susceptible to changes in temperature and humidity.

In one embodiment, a first plurality of devices on the first substrate are connected to a first pad and a second plurality of devices on the second substrate are connected to a second pad, and the first pad the second pad are connected at the bonding interface. The pads provide an ideal way to form the hybrid bond.

In one embodiment, a third substrate includes a die portion, a crackstop structure, and a hybrid bond interface. The hybrid bond interface of the third substrate is adjacent the second substrate and faces the hybrid bond interface of the first substrate to form a hybrid bond with the first substrate. A structure with a base substrate and two more substrate structures that are bonded to the base substrate may provide for more flexibility in arranging voids for microcrack stoppage.

According to one embodiment, a conjoined semiconductor device includes a first wafer and a second wafer, each wafer having a joining surface and joining pads. A plurality of void patterns adjacent the joining pads are formed in the first wafer and/or the second wafer. The first wafer and the second wafer are hybrid bonded to each other at the joining pads. The use of void patterns may enhance the microcrack stoppage capability of the semiconductor structure.

In one embodiment, at least some of the plurality of void patterns are formed in the joining surface of the first wafer and/or the second wafer. Arrangement of the void patterns in the joining surface can prevent microcracks propagation along the interface.

In one embodiment, the plurality of void patterns alternate between the joining surface of the first wafer and the joining surface of the second wafer. The spreading out of the void patterns provides the stopping of microcracks over a larger area.

In one embodiment, at least some of the void patterns are arranged adjacent the joining pads and are smaller than a height of the joining pads. The smaller void patterns can be particularly effective against internal stresses.

In one embodiment, the joining pads are metallic joining pads, and the void patterns have a varying depth into respective Back-End-Of-Line (BEOL) stacks of the joining surface. The varying depths cause differently sized airgaps and can stop microcracks from different stresses such as internally created stresses.

According to embodiment, a method of manufacturing a hybrid bond crackstop structure with voids includes providing a first substrate and a second substrate, each of the first substrate and the second substrate including a die portion and at least one crackstop structure adjacent the die portion. A hybrid bond interface is formed between an upper surface of the first substrate and the second substrate. The first substrate and the second substrate are hybrid bonded at the hybrid bond interface. One or more voids are patterned adjacent the hybrid bond interface. By patterning the voids after the structure is hybrid bonded may facilitate an easier construction than first making the voids in each of the first and second substrates.

In one embodiment, prior to the hybrid bonding of the first substrate and the second substrate, a resist layer is arranged on each hybrid bond interface, and a patterning of a first void in the upper surface of the first substrate and a second void in the second substrate that are substantially aligned is performed. The resist layer is removed, and the first substrate and the second substrate are hybrid bonded. A single unified void with airgaps is formed from the substantially aligned first void and second void. The single unified void with airgaps extends across the hybrid bond interface. This structure provides a way to align the two structures including the voids to create a unified void, and prevents microcracks from propagating along the interface and damaging the dies.

In one embodiment, the patterning of voids is created around individual metallic joining pads by creating a topography on the surface of each substrate prior to joining by hybrid bonding. A macroscopic hybrid joining pattern is created including metal pad surfaces joined to metal pad surfaces, dielectric surfaces joined to dielectric surfaces and voids joined to voids. This patterning of voids provides for more effective stoppage of propagating microcracks.

### BRIEF DESCRIPTION OF THE DRAWINGS

The drawings are of illustrative embodiments. They do not illustrate all embodiments. Other embodiments may be used in addition to or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1A illustrates a joined semiconductor structure having at least one microcrack.

FIG. 1B illustrates a hybrid bonded semiconductor structure with an enlarged portion of the hybrid bond junction showing the path of a microcrack.

FIG. 2 illustrates a structure for hybrid bond crackstops with voids for airgaps, consistent with an illustrative embodiment.

FIG. 3 illustrates a structure for hybrid bond crackstops with multiple voids for airgaps, consistent with an illustrative embodiment.

FIG. 4 illustrates a structure for hybrid bond crackstops with multiple voids for airgaps, and an extended crackstop structure, consistent with an illustrative embodiment.

FIGS. 5A, 5B and 5C illustrate various types of voids within the crackstop architecture of hybrid bonded semiconductor structures, consistent with an illustrative embodiment.

FIGS. 5D, 5E and 5F show void patterns in contiguous circles, dashed circles, and circles with a grid consistent with an illustrative embodiment.

FIGS. 5G, 5H and 5I show rotated view of the arrangements of patterns in FIGS. 5D, 5E and 5F respectively, consistent with an illustrative embodiment.

FIG. 5J shows another pattern with a three-d view and a rotated view consistent with an illustrative embodiment.

FIGS. 6A and 6B illustrate void patterns in each semiconductor that bridge across the joining bond interface, consistent with an illustrated embodiment.

FIG. 6C illustrates gaps etched out that range across the joining bond interface consistent with an illustrative embodiment.

FIG. 6D illustrates an alternative arrangement of new gaps in the hybrid bond area consistent with an illustrative embodiment.

FIG. 7 illustrates hybrid joining pads with various pattern arrangements and different types of voids integrated into the joining pattern, consistent with an illustrative embodiment.

FIG. 8 illustrates a process flow for creating a semiconductor structure with a hybrid bond and voids to create airgaps, consistent with an illustrative embodiment.

FIG. 9 is a flowchart illustrating some of the operations for a method of making a semiconductor structure with a hybrid and voids for airgaps, consistent with an illustrative embodiment.

### DETAILED DESCRIPTION

In the following detailed description, numerous specific details are set forth by way of examples to provide a thorough understanding of the relevant teachings. However, it is to be understood that the present teachings may be practiced without such details. In other instances, well-known methods, procedures, components, and/or circuitry have been described at a relatively high level, without detail, to avoid unnecessarily obscuring aspects of the present teachings. It is also to be understood that the present disclosure is not limited to the depictions in the drawings, as there may be fewer elements or more elements than shown and described.

In discussing the present technology, it may be helpful to describe various salient terms. In one aspect, spatially related terminology such as “front,” “back,” “top,” “bottom,” “beneath,” “below,” “lower,” above,” “upper,” “side,” “left,” “right,” and the like, is used with reference to the direction of the Figures being described. Since components of embodiments of the disclosure can be positioned in a number of different directions, the directional terminology is used for purposes of illustration and is in no way limiting. Thus, it will be understood that the spatially relative terminology is intended to encompass different directions of the device in use or operation in addition to the direction depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other directions) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together—intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or logical changes may be made without departing from the spirit and scope defined by the claims. The description of the embodiments is not limiting. In particular, elements of the embodiments described hereinafter may be combined with elements of different embodiments.

As used herein, certain terms are used to describe the openings made to arrest the development of microcracks. A person of ordinary skill is to understand that the terms voids, cavities, trenches all refer to a space in the surface of the joining interface, substrate, or dielectric. For ease of description, the disclosure uses the term “voids” throughout.

Although the terms first, second, third, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or logical changes may be made without departing from the spirit and scope defined by the claims. The description of the embodiments is not limiting. In particular, elements of the embodiments described hereinafter may be combined with elements of different embodiments.

### Overview

The present disclosure presents a structure and method for hybrid bond crackstops with airgaps. The present disclosure also discloses a structure and method for a hybrid bond joining interface with airgaps incorporated into a pattern.

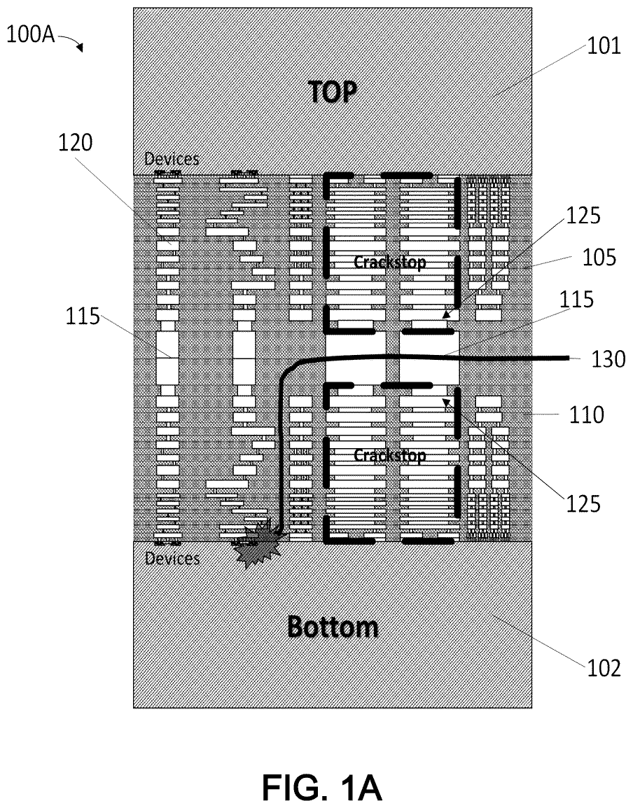

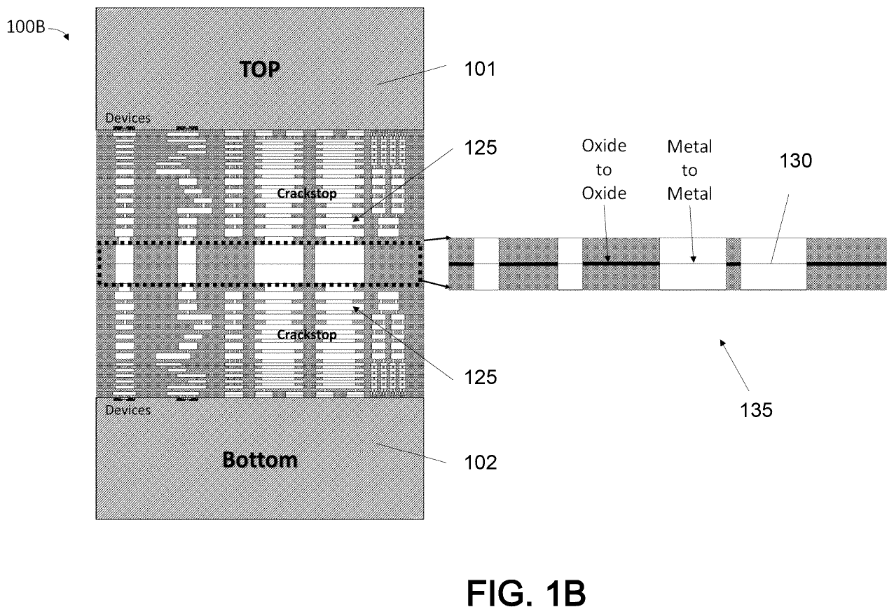

FIG. 1A shows an example of a joined semiconductor structure 100A, in which a first substrate 101 and a second substrate 102 have respective dielectric layers 105, 110 thereon. The first substrate 101 and the second substrate 102 are joined by hybrid bonding. There is an interface 115 at the junction interface between two crackstops 125 and two columns of devices 120, (sometimes referred to as dies). In current hybrid bonding there is an interface 115 at the junction/interface between the crackstops 125 (shown in the dashed boxes) and the two devices 120. This interface 115 can be increased in size by microcracks 130 to separate the first and second bonded substrates, or to serve as an access entry point from which the microcrack 130 could bypass the crackstop 125 structures and potentially propagate down into stack of dies within the prime active region, as shown. A microcrack 130 shown in FIG. 1A propagates far enough to reach the devices 120 and may result in catastrophic die failure.

The embodiments of the present disclosure are directed to creating airgaps by placing trenches, cavities, or voids (hereinafter collectively referred to as “voids”) across the hybrid joint to arrest the propagation of the cracks along the hybrid bond junction of the two substrates. The voids can stop/reduce the incidence of cracks caused both by external stresses (e.g., from dicing the wafer, and from heat, moisture and bonding pressure) and internal stresses (e.g., nascent cracks from the manufacturing process) and may be sized differently and arranged adjacent the crackstops and devices to prevent the propagation of microcracks. The growth and propagation of the microcracks are arrested by the airgaps created by the voids.

FIG. 1B illustrates a hybrid bonded semiconductor 100B structure with an enlarged portion of the hybrid bond junction 135 to show the path of a microcrack 130. Although there are several crackstops 125 present, the microcrack 130 can still propagate between the junctions of both metal to metal, and oxide to oxide junctions shown.

### Example Architecture

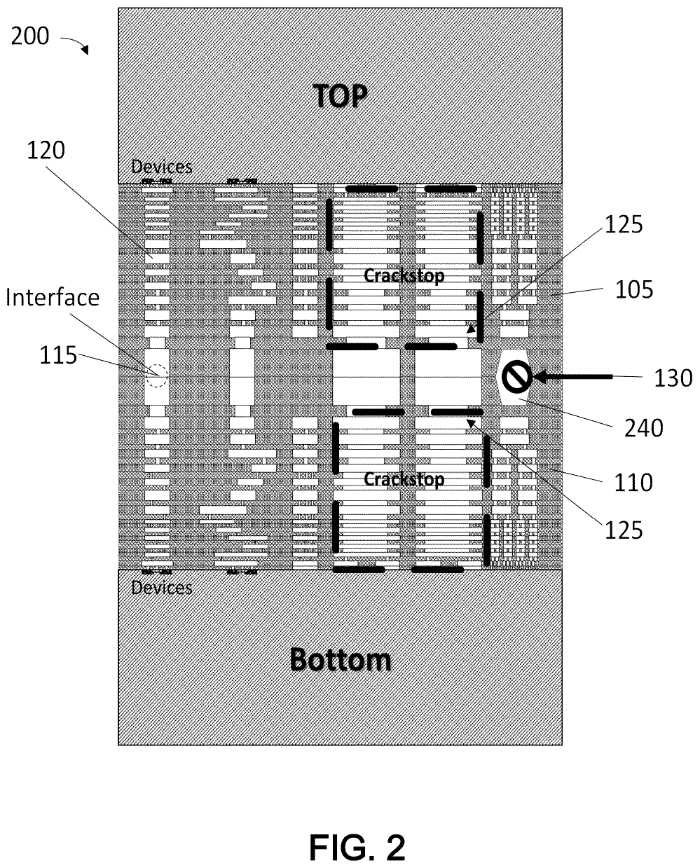

FIG. 2 illustrates a structure 200 for hybrid bond crackstops with airgaps, consistent with an illustrative embodiment. Similar to FIG. 1A, the structure of FIG. 2 illustrates the first substrate 101 and the second substrate 102, having dielectric layers 105, 110 thereon. The first substrate 101 and the second substrate 102 are joined together by hybrid bonding. There is also the interface 115 (a portion of which is circled) at the junction interface between two crackstops 125 and two columns of devices 120.

Still referring to FIG. 2, there is shown an example of a void 240 arranged across the junction of the first substrate and the second substrate. The void 240 creates an airgap that stops the microcrack 130 from spreading across the structure. The circle with the slanted line shows the microcrack 130 is arrested and does not further propagate because of the void 240.

### Example Embodiments

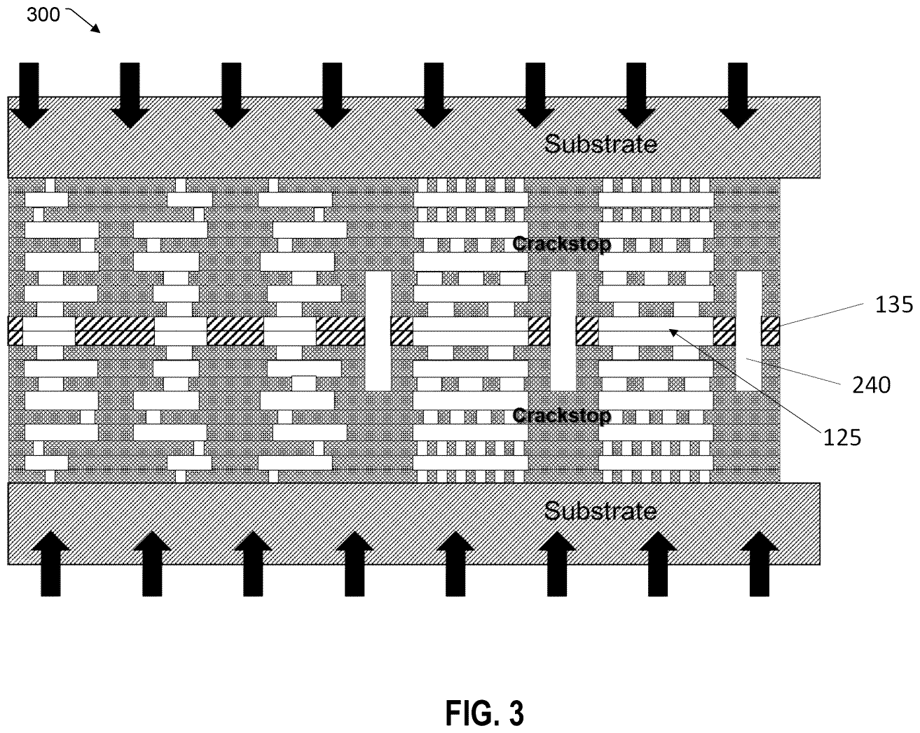

FIG. 3 illustrates a structure 300 for hybrid bond crackstops with multiple voids for airgaps, consistent with an illustrative embodiment. In FIG. 3, the basic concept of arranging the voids 240 across the hybrid bond junction is to remove the material the crack is propagating in, and prevents a forward progression. It is to be noted that the crackstops 125 stop before the hybrid junction, thus the voids 240 can prevent the crack from propagating along the hybrid junction as shown in FIGS. 1B and 1C.

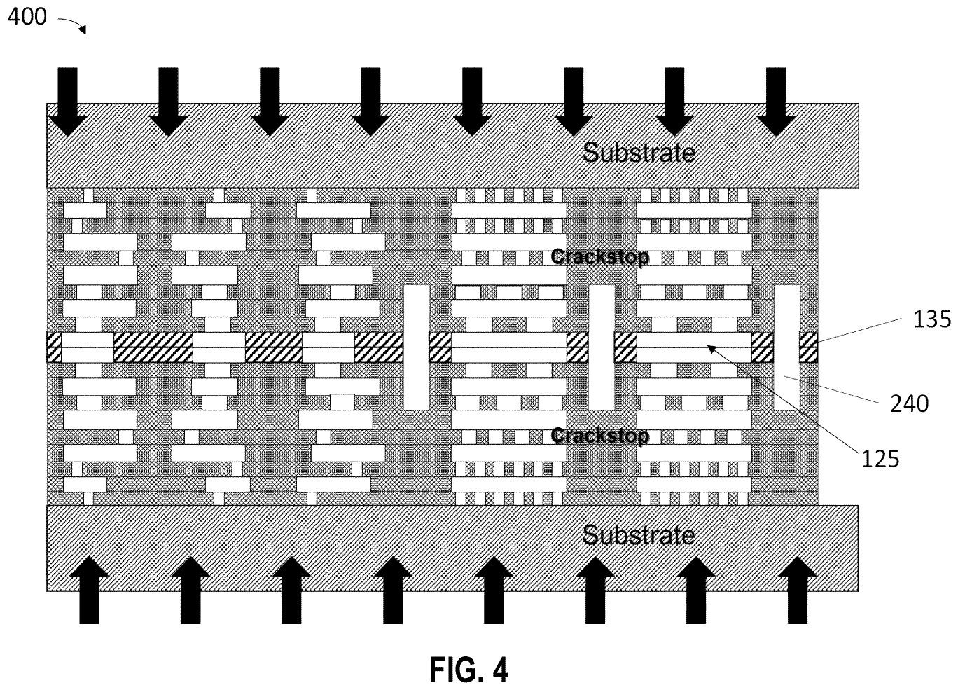

FIG. 4 illustrates a structure 400 for hybrid bond crackstops with multiple voids for airgaps, and an extended crackstop structure, consistent with an illustrative embodiment. FIG. 4 differs from FIG. 3 at least in that the crackstops 125 of the first substrate 301 and the second substrate 301 are connected across the hybrid bond junction 135. However, the additional voids 240 add an extra measure of protection against microcracks possibly getting past the crack stops and damaging the devices 120, as the airgaps created by the voids 240 along with the crackstops 125 arrest more cracks than the crackstops 125 alone.

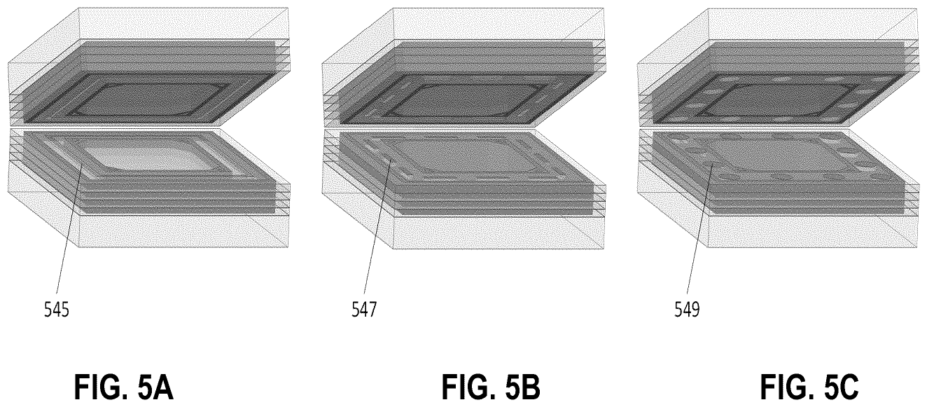

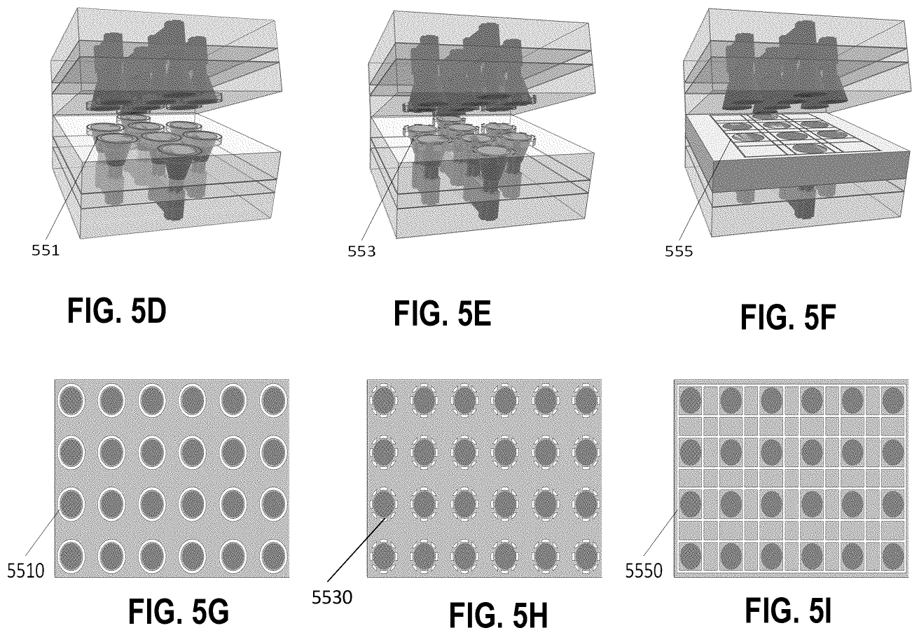

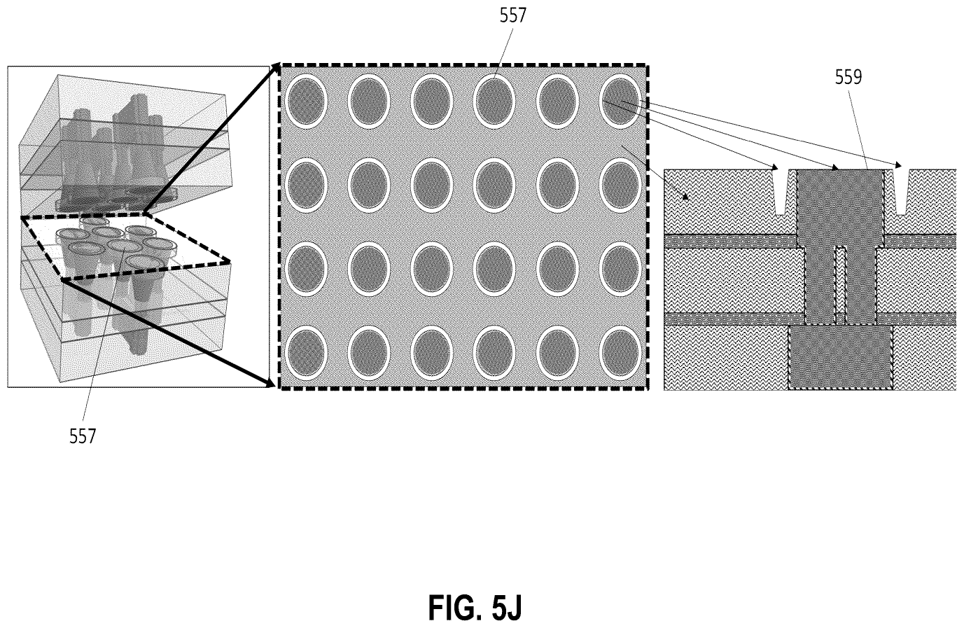

FIGS. 5A, 5B and 5C illustrate various types of voids incorporated into the crackstop design surrounding the periphery of the hybrid bonded semiconductor structures, consistent with an illustrative embodiment. The voids shown are ring-shaped 545, non-contiguous 547, and circular 549. It is to be understood that the disclosure is not limited to only the voids shown and described, and the different shapes in FIGS. 5A, 5B and 5C are presented for illustrative purposes.

FIGS. 5D, 5E and 5F show void patterns in contiguous circles, dashed circles, and circles with a grid consistent with an illustrative embodiment. FIG. 5A shows contiguous circle void patterns. FIG. 5E shows non-contiguous circle patterns 553. FIG. 5F shows circular patterns 555 within a grid.

FIGS. 5G, 5H and SI show a rotated view of the arrangements of patterns in FIGS. 5D, 5E and 5F respectively, consistent with an illustrative embodiment. The contiguous circles 5510 are shown in FIG. 5G. FIG. 5H shows the noncontiguous patterns 5530. FIG. 5I shows the circular pattern 5550 within a grid.

FIG. 5J shows a modified circular void pattern 557 with a three-dimensional view 5557 view and a rotated view 559 consistent with an illustrative embodiment. The gaps in the circular patterns are shown in the rotated view 559.

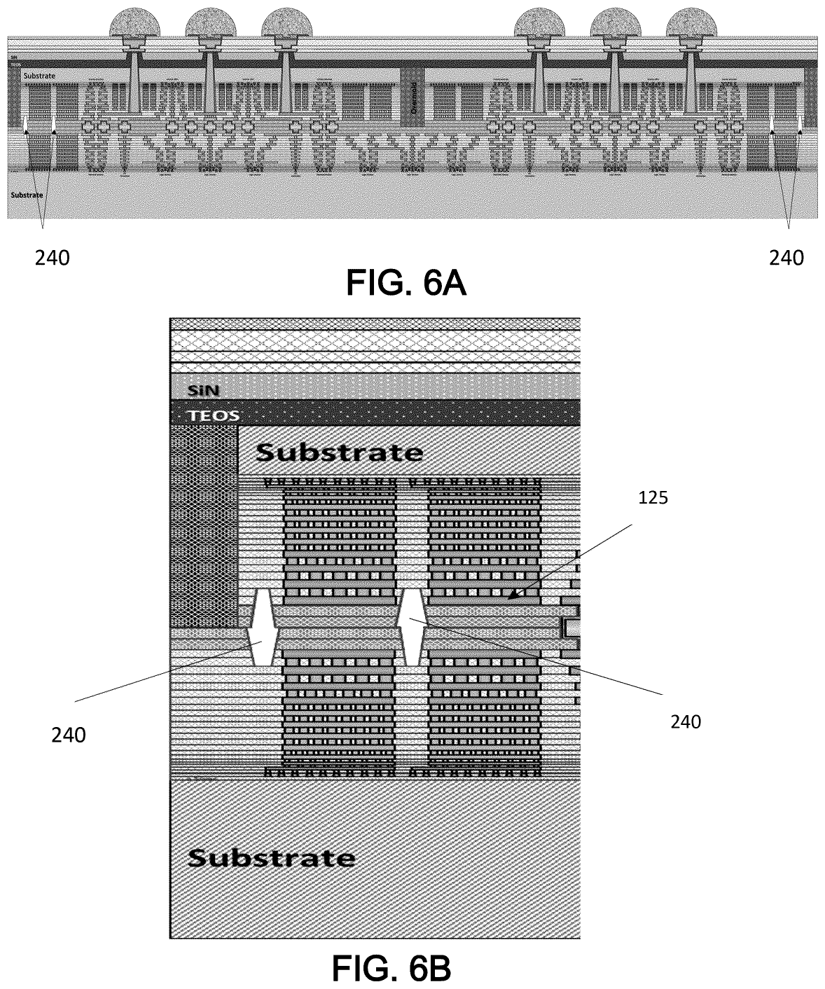

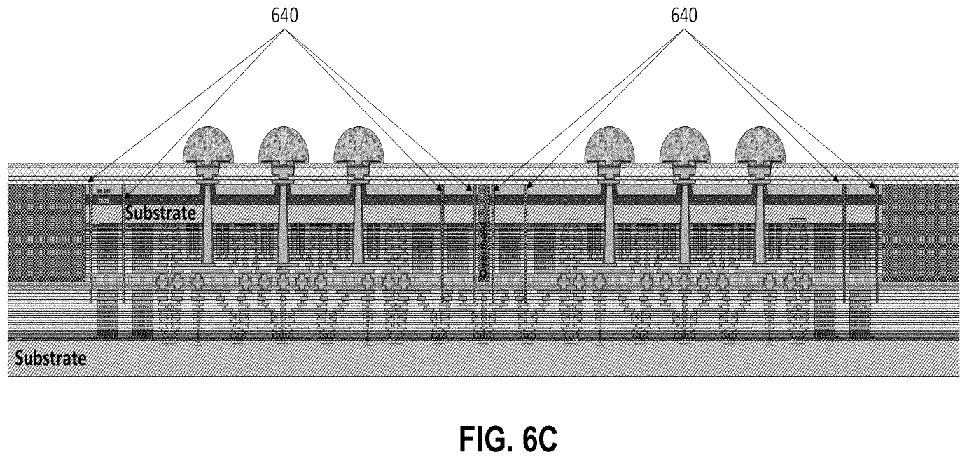

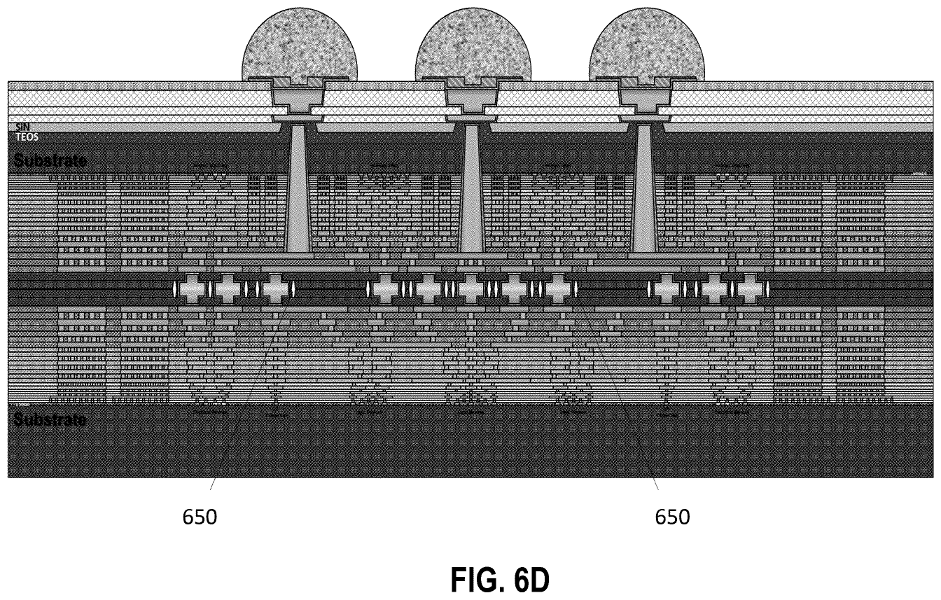

FIGS. 6A and 6B illustrate void patterns in each semiconductor that bridge across the joining bond interface located within the cojoined crackstop design and surrounding the periphery of the active device region of hybrid bond adjoined semiconductor build. FIG. 6A shows voids 240 patterned in each individual semiconductor build that have been joined to create a single unified void that bridges across joining bond interface. FIG. 6B shows varying sized voids 240 to assist with alignment. In FIG. 6B, the two voids 240 appear to have a smaller void and a larger void connected to make the unified void.

FIG. 6C illustrates gaps etched out that range across the joining bond interface consistent with an illustrate embodiment. The gaps 640 etched out that crosses across bond interface after the die-to-die bonding. The gaps may be filled with underfill and/or overmold, etc.

FIG. 6D illustrates an alternative arrangement of new gaps in the hybrid bond area consistent with an illustrative embodiment. The new gaps 650 are arranged in the hybrid bond area. These gaps 650 may be, for example, etched into the hybrid bond area.

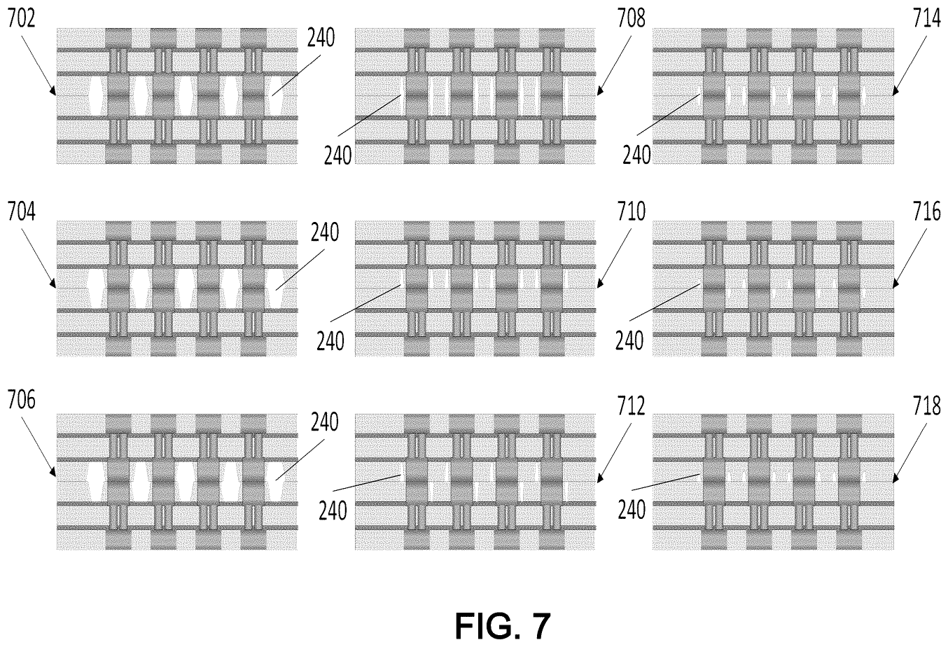

FIG. 7 illustrate structures with various pattern arrangements and different types of voids positioned about and around hybrid joining pads, consistent with an illustrative embodiment. It is to be understood that in this embodiment, the voids are arranged around the electrically connected hybrid joining pads of the active device prime region. These voids are provided to address inherent intrinsic defects that result from the joining process and structures themselves. While the previously-described voids that were shown and described addressed external extrinsic cracks/defects results from external forces such as dicing, etc. In contrast to voids addressing external caused and/or extrinsic cracks/defects, the voids around the periphery of the die surrounding active prime region are more discrete and located about and around active electrically connection portions of the device. The voids 240 are in various shapes and patterns, each having different airgaps to stop microcracks from both external and internal stresses. For example, structure 702 illustrates symmetrically shaped voids 240. Structure 704 shows voids 240 in which one portion is sized differently than the other. Structure 706 shows the voids are arranged with alternating orientations (as compared with structure 704). The varied sizes of the voids 240 shown in structures 702, 704 and 704 is to facilitate alignment of the structures that are hybrid bonded.

Still referring to FIG. 7, the voids 240 of structure 706 is much thinner than, for example, the voids 240 in structures 702, 704 and 706. Structure 710 illustrates voids 240 arranged on only one of the joined structures, and structure 712 shows alternating arrangements.

Structures 714, 716 and 718 show voids 240 partially etched in the top dielectric layer. For example, structure 714 has relatively shorter voids 240 than used in structure 708. Structures 716 and 718 are similar in the arrangement of the voids than structures 710 and 712, but the voids 240 in structure 716 and 716 are shorter than structures 710 and 712.

### Example Process

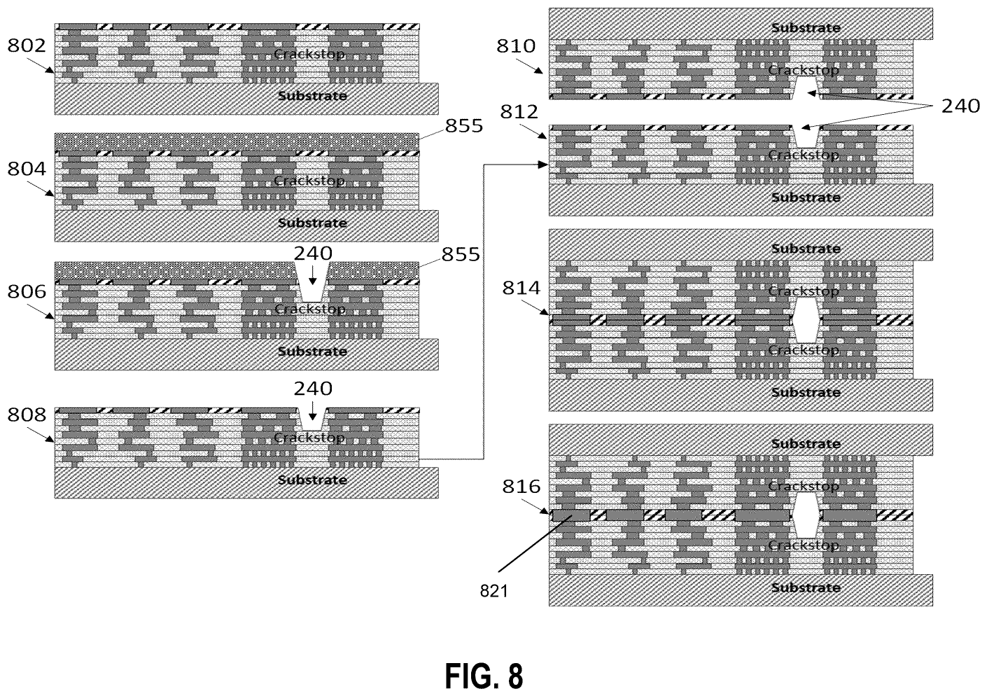

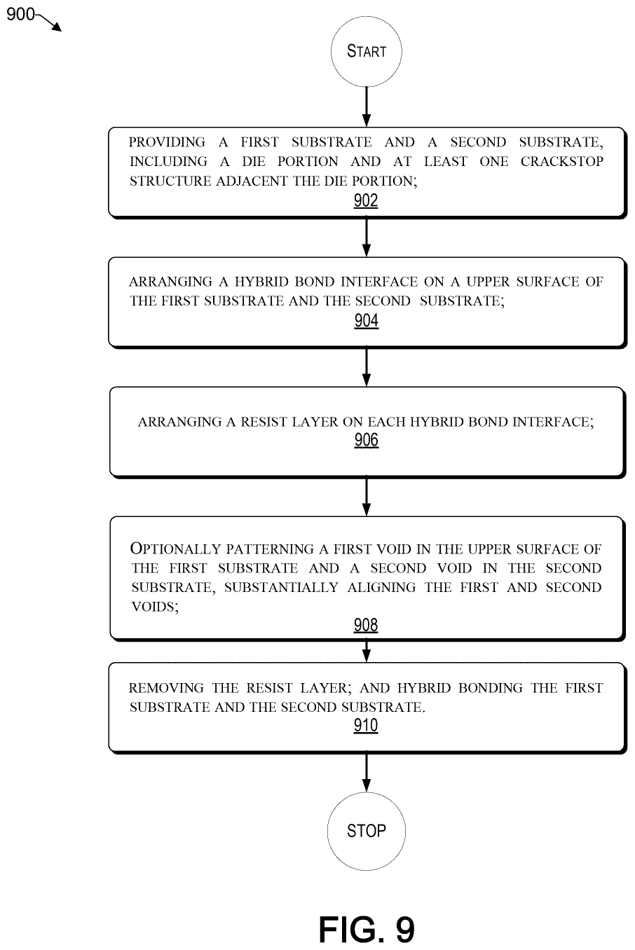

With the foregoing overview of the example architecture, it may be helpful now to consider a high-level discussion of an example process. To that end, FIG. 8 is a process flow for creating a semiconductor structure with a hybrid bond and voids to create airgaps, consistent with an illustrative embodiment. FIG. 9 is a flowchart 900 illustrating some of the operations for a method of making a semiconductor structure with a hybrid junction and voids for airgaps, consistent with an illustrative embodiment. It is to be understood that the process shown and described is provided for illustrative purposes, and the present disclosure is not limited to creating voids in the manner described in the process of FIG. 9. For example, voids may be created in other ways (including but not limited to etching) and thus illustrates one particular non-limiting technique or process flow that may be used.

Referring to FIG. 8, a structure 802 includes a substrate with dielectric layers, crackstops and devices on the substrate. Structure 804 shows a resist layer 855 is added to the top of the joining junction. Structure 806 shows a void 240 that is made in the resist layer 855 and the semiconductor below. Structure 810 shows the resist layer 855 is removed from the joining junction. Structure 812 shows a first substrate and a second substrate aligned at the voids 240. Structure 814 shows the two substrate structures hybrid bonded. It is shown that the void 240 bridges across the hybrid bonded junction.

FIG. 9 is shown as a collection of blocks, in a logical order, which represents a sequence of operations that can be implemented in a combination thereof.

At operation 902, a first substrate and a second substrate are provided, each of the first substrate and the second substrate including a die and at least one crackstop structure adjacent the die portion. FIG. 8 shows an example of a structure 802 having the die and the crackstop.

At operation 904, a hybrid bond interface is arranged on an upper surface of the first substrate and the second substrate. The hybrid bond interface may be similar to the example shown in FIG. 1B. The hybrid bond interface may have oxide portions and metallic portions.

At operation 906, a resist layer is arranged on each hybrid bond interface. FIG. 8 shows in structure 804 a resist layer 855 arranged on the hybrid bond interface.

At operation 908, a first void is patterned in the upper surface of the first substrate and a second void in the second substrate. The first void and the second void are substantially aligned. Structure 810 shows one non-limiting example of the aligned substrates. It is to be understood that operation 908 is optional. For example, the structures may be hybrid bonded at operation 910 (described below), and then voids may be etched into the substance. The arranging of the voids after the hybrid bonding may facilitate the hybrid joined structure with less aligning efforts require than if voids are first patterned in the substrate surfaces prior to joining.

At operation 910, the resist layer is removed, and the first substrate and the second substrate are hybrid bonded. FIG. 8 shows structure 814, which is the hybrid bonded structure with the void arranged between the crack stops and bridging the hybrid bond interface.

The method ends after operation 910. It is to be understood that there may be additional voids of various sizes and positions arranged on the first and second substrates prior to the hybrid bonding operation.

### Conclusion

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, operations, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any such actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A hybrid bonded semiconductor structure, comprising:
a first substrate and a second substrate each having an interface joined in a hybrid bond;
each substrate including a die portion and a crackstop structure adjacent the die portion; and
one or more voids formed in the first substrate and the second substrate about a portion of a periphery of each crackstop structure,
wherein at least some of the one or more voids in the first substrate and the second substrate are substantially aligned to form a unified void with airgaps across the hybrid bond interface.

2. The semiconductor structure according to claim 1, wherein the crackstop structure of the first substrate and the second substrate is joined at the hybrid bond interface.

3. The semiconductor structure according to claim 1, wherein at least some of the voids formed in each of the first substrate and the second substrate are differently shaped.

4. The semiconductor structure according to claim 1, wherein the one or more voids comprise a plurality of voids at least some of which are differently sized.

5. The semiconductor structure according to claim 1, further comprising a plurality of voids arranged in succession extending across the hybrid bond interface.

6. The semiconductor structure according to claim 1, wherein:
each hybrid bond interface comprises a back-end-of-line (BEOL) interconnect level, and
the unified void is a least partially filled with a dielectric or a polysilicon material that is different from a material of the hybrid bond interface.

7. The semiconductor structure according to claim 1, wherein the one or more voids in the first substrate and the second substrate are ring-shaped.

8. The semiconductor structure according to claim 1, wherein the one or more voids in the first substrate and the second substrate are arranged as non-contiguous rings.

9. The semiconductor structure according to claim 1, wherein the one or more voids in the first substrate and the second substrate are as circular-shaped.

10. The semiconductor structure according to claim 1, wherein the one or more voids are filled with a material that is different from a material forming the crackstop structure and/or the hybrid bond interface.

11. The semiconductor structure according to claim 1, further comprising a first plurality of devices on the first substrate connected to a first pad and a second plurality of devices on the second substrate connected to a second pad, wherein the first pad and the second pad are connected at the hybrid bond interface.

12. The semiconductor structure according to claim 1, further comprising a third substrate including a die portion, a crackstop structure, and a hybrid bond interface, wherein the hybrid bond interface of the third substrate is adjacent the second substrate and faces the hybrid bond interface of the first substrate to form a hybrid bond with the first substrate.

13. A conjoined semiconductor device, comprising:
a first wafer and a second wafer, each wafer having a joining surface and joining pads, and
a plurality of void patterns are formed adjacent the joining pads in the first wafer and/or the second wafer,
wherein the first wafer and the second wafer are hybrid bonded to each other at the joining pads.

14. The conjoined semiconductor device according to claim 13, wherein at least some of the plurality of void patterns are formed in the joining surface of the first wafer and/or the second wafer.

15. The conjoined semiconductor device according to claim 13, wherein the plurality of void patterns alternate between the joining surface of the first wafer and the joining surface of the second wafer.

16. The conjoined semiconductor device according to claim 13, wherein at least some of the void patterns are arranged adjacent the joining pads and are smaller than a height of the joining pads.

17. The conjoined semiconductor device according to claim 13, wherein:
the joining pads comprise metallic joining pads; and
the void patterns have a varying depth into respective Back-End-Of-Line (BEOL) stacks of the joining surface.

18. A method of manufacturing a hybrid bond crackstop structure with voids, the method comprising:
providing a first substrate and a second substrate, each of the first substrate and the second substrate including a die portion and at least one crackstop structure adjacent the die portion;
arranging a hybrid bond interface on an upper surface of the first substrate and the second substrate;
hybrid bonding the first substrate and the second substrate; and
patterning one or more voids adjacent the hybrid bond interface.

19. The method according to claim 18, wherein prior to performing the hybrid bonding of the first substrate and the second substrate:
arranging a resist layer on each hybrid bond interface;
patterning a first void in the upper surface of the first substrate and a second void in the second substrate, wherein the first void and the second void are substantially aligned;
removing the resist layer; and
forming a single unified void with airgaps from the substantially aligned first void and second void, wherein the single unified void with airgaps extends across the hybrid bond interface.

20. The method according to claim 18, further comprising:
patterning voids created around individual metallic joining pads by creating a topography on the surface of each substrate prior to joining by hybrid bonding; and
creating a macroscopic hybrid joining pattern comprising metal pad surfaces joining to metal pad surfaces, dielectric surfaces joining to dielectric surfaces and voids joining to voids.
